(19) United States
(12) Patent Application Publication
(10) Pub. No.: US 2011/0121719 A1
(43) Pub. Date: May 26, 2011

(54) ORGANIC EL DEVICE AND MANUFACTURING METHOD THEREOF

(76) Inventors: Shuhei Yokoyama, Ishikawa-gun (JP); Shiro Sumita, Kanazawa-shi (JP); Masuyuki Oota, Hakusan-shi (JP); Hiroshi Sano, Yokkaichi-shi (JP)

(21) Appl. No.: 12/952,980

(22) Filed: Nov. 23, 2010

(30) Foreign Application Priority Data
Nov. 25, 2009 (JP) 2009-267759

(51) Int. Cl. H01L 27/32; H01L 51/56

(52) U.S. Cl. 313/504; 438/31; 257/E51.02

(57) ABSTRACT

According to one embodiment, an organic EL device includes an insulative substrate, a switching element above the insulative substrate, an insulation film above the switching element and includes a contact hole reaching the switching element, a pixel electrode above the insulation film and includes a contact portion extending into the contact hole and electrically connected to the switching element, an organic layer extending over the pixel electrode including the contact portion, and extending over the insulation film in a vicinity of the pixel electrode, and a counter-electrode above the organic layer.

### CROSS-REFERENCE TO RELATED APPLICATIONS

This application is based upon and claims the benefit of priority from Japanese Patent Application No. 2009-267759, filed Nov. 25, 2009; the entire contents of which are incorporated herein by reference.

### FIELD

Embodiments described herein relate generally to an organic electroluminescence (EL) device and a manufacturing method thereof.

### BACKGROUND

In recent years, display devices using organic electroluminescence (EL) elements have vigorously been developed, which have features of self-emission, a high response speed, a wide viewing angle and a high contrast, and which can realize further reduction in thickness and weight.

In the organic EL element, holes are injected from a hole injection electrode (anode), electrons are injected from an electron injection electrode (cathode), and the holes and electrons are recombined in a light emitting layer, thereby producing light. In order to obtain full-color display, it is necessary to form pixels which emit red (R) light, green (G) light and blue (B) light, respectively. It is necessary to selectively apply light-emitting materials, which emit lights with different light emission spectra, such as red, green and blue, to light-emitting layers of organic EL elements which constitute the red, green and blue pixels. As a method for selectively applying such light-emitting materials, there is known a vacuum evaporation method. In the case of forming films of low-molecular-weight organic EL materials by such a vacuum evaporation method, there is a method in which mask evaporation is performed independently for respective color pixels by using a metallic fine mask having openings in association with the respective color pixels (see, e.g. Jpn. Pat. Appln. KOKAI Publication No. 2003-157973).

### BRIEF DESCRIPTION OF THE DRAWINGS

FIG. 1 is a cross-sectional view which schematically shows the structure of a display panel including switching elements and first to third organic EL elements of an organic EL display device in the embodiment;

FIGS. 2A, 2B, 2C, 2D and 2E are top views which schematically show the positional relationship between pixel electrodes and contact holes in the first to third organic EL elements shown in FIG. 1;

FIG. 3 is a cross-sectional view which schematically shows a cross-sectional structure of a second organic EL element, taken along line III-III in FIG. 2B;

FIG. 4 is a cross-sectional view of an array substrate including switching elements and first to third organic EL elements of an organic EL display device according to another structure example of the embodiment;

FIG. 5 is a cross-sectional view of an array substrate including switching elements and first to third organic EL elements of an organic EL display device according to still another structure example of the embodiment;

FIGS. 6A, 6B, 6C, 6D and 6E are top views which schematically show the positional relationship between pixel electrodes and contact holes in the first to third organic EL elements shown in FIG. 5;

FIG. 7 is a cross-sectional view of an array substrate including switching elements and first to third organic EL elements of an organic EL display device according to still another structure example of the embodiment;

FIGS. 8A, 8B, 8C, 8D and 8E are top views which schematically show the positional relationship between pixel electrodes and contact holes in the first to third organic EL elements shown in FIG. 7;

FIG. 9 is a flow chart for describing a method of manufacturing an array substrate shown in FIG. 1;

FIG. 10 is a flow chart for describing a method of manufacturing array substrates shown in FIG. 5 and FIG. 7; and

FIG. 11 is a cross-sectional view of an array substrate including switching elements and first to third organic EL elements of an organic EL display device according to still another structure example of the embodiment.

### DETAILED DESCRIPTION

In general, according to one embodiment, an organic EL device comprises an insulative substrate; a switching element above the insulative substrate; an insulation film above the switching element and comprising a contact hole reaching the switching element; a pixel electrode above the insulation film and comprising a contact portion extending into the contact hole and electrically connected to the switching element; an organic layer extending over the pixel electrode including the contact portion, and extending over the insulation film in a vicinity of the pixel electrode; and a counter-electrode above the organic layer.

In the drawings, structural elements having the same or similar functions are denoted by like reference numerals, and an overlapping description is omitted.

In the present embodiment, as an example of the organic EL device, a description is given of an organic EL display device which adopts an active matrix driving method.

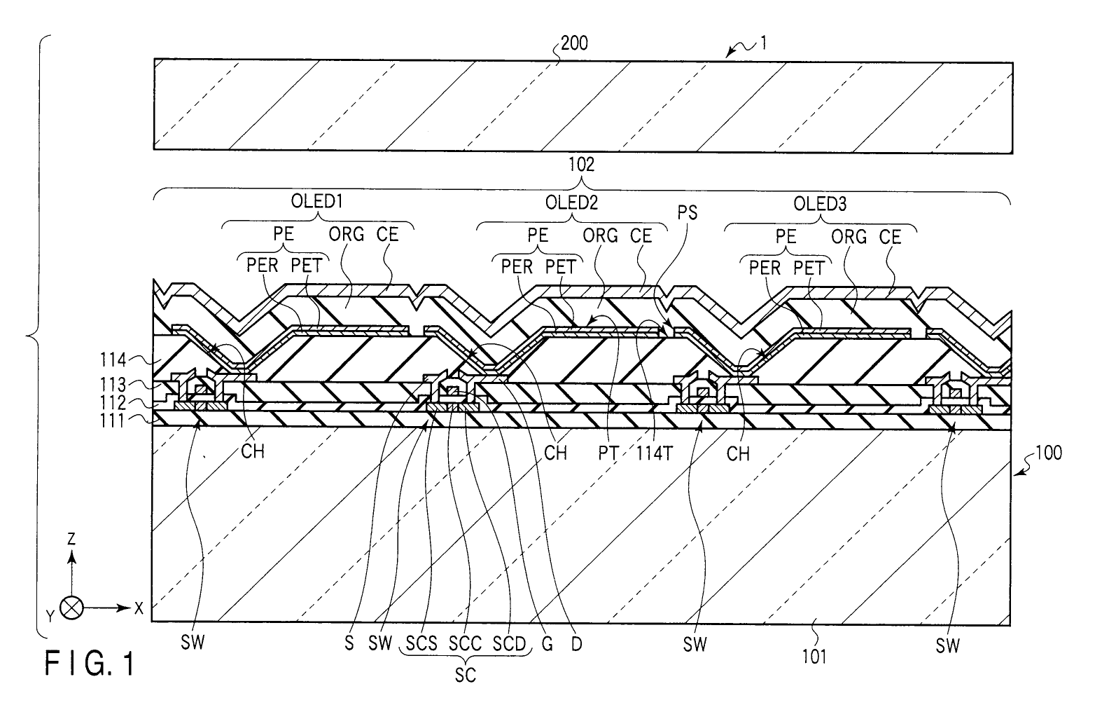

FIG. 1 is a cross-sectional view of a display panel 1 which includes switching elements SW and first to third organic EL elements OLED1 to OLED3 of the organic EL display device according to the embodiment. Each of the first to third organic EL elements OLED1 to OLED3 is of a top emission type in which light is radiated from the side of a counter-substrate 200. In the embodiment, however, each of the first to third organic EL elements OLED1 to OLED3 may be of a bottom emission type in which light is radiated from the side of an array substrate 100.

The array substrate 100 includes an insulative substrate 101 having light transmissivity, such as a glass substrate or a plastic substrate. The switching elements SW and first to third organic EL elements OLED1 to OLED3 are disposed above the insulative substrate 101 in an active area 102 for displaying an image.

A first insulation film 111 is disposed on the insulative substrate 101. The first insulation film 111 extends over almost the entirety of the active area 102. The first insulation film 111 is formed of, for example, an inorganic compound such as silicon oxide or silicon nitride.

A semiconductor layer SC of the switching element SW is disposed on the first insulation film 111. The semiconductor layer SC is formed of, e.g. polysilicon. In the semiconductor layer SC, a source region SCS and a drain region SCD are formed, with a channel region SCC being interposed therebetween.

The semiconductor layer SC is covered with a second insulation film 112. The second insulation film 112 is also disposed on the first insulation film 111. The second insulation film 112 extends over almost the entirety of the active area 102. The second insulation film 112 is formed of, for example, an inorganic compound such as silicon oxide or silicon nitride.

A gate electrode G of the switching element SW is disposed on the second insulation film 112 immediately above the channel region SCC. In this example, the switching element SW is a top-gate type p-channel thin-film transistor (TFT). The gate electrode G is covered with a third insulation film 113. The third insulation film 113 is also disposed on the second insulation film 112. The third insulation film 113 extends over almost the entirety of the active area 102. The third insulation film 113 is formed of, for example, an inorganic compound such as silicon oxide or silicon nitride.

A source electrode S and a drain electrode D of the switching element SW are disposed on the third insulation film 113. The source electrode S is put in contact with the source region SCS of the semiconductor layer SC. The drain electrode D is put in contact with the drain region SCD of the semiconductor layer SC. The gate electrode G, source electrode S and drain electrode D of the switching element SW are formed of an electrically conductive material such as molybdenum (Mo), tungsten (W), aluminum (Al) or titanium (Ti).

The source electrode S and drain electrode D are covered with a fourth insulation film 114. The fourth insulation film 114 is also disposed on the third insulation film 113. The fourth insulation film 114 extends over almost the entirety of the active area 102. The fourth insulation film 114 is disposed above the switching elements SW, and functions as an insulative film which becomes an underlying layer of a pixel electrodes PE. Specifically, the fourth insulation film 114 is disposed between the switching elements SW and the first to third organic EL elements OLED1 to OLED3.

The fourth insulation film 114 is formed of an organic compound such as an ultraviolet-curing resin or a thermosetting resin. For example, the fourth insulation film 114 is formed of at least one of an acryl radical-containing resin, a polyimide radical-containing resin, a silicone radical-containing resin, a fluorine radical-containing resin, a urethane radical-containing resin and an epoxy radical-containing resin. Alternatively, the fourth insulation film 114 may be formed of a material in which at least one black coloring material, which is selected from among carbon black, acetylene black, lampblack, bone black, graphite, iron black, aniline black, cyanine black, titanium black and an iron oxide-based black pigment, is mixed in a matrix of at least one of an acryl radical-containing resin, a polyimide radical-containing resin, a silicone radical-containing resin, a fluorine radical-containing resin, an urethane radical-containing resin and an epoxy radical-containing resin.

Contact holes CH, which form recesses reaching the switching elements SW, are formed in the fourth insulation film 114. Specifically, a part of the drain electrode D of the switching element SW is located at the bottom of the contact hole CH.

Each of the pixel electrodes PE, which constitute the first to third organic EL elements OLED1 to OLED3, is disposed on the fourth insulation film 114. The pixel electrode PE of each of the first to third organic EL elements OLED1 to OLED3 extends into the contact hole CH, and is electrically connected to the drain electrode D of the switching element SW. The pixel electrodes PE correspond to, e.g. anodes. The pixel electrodes PE are separated from each other, and the fourth insulation film 114 between the neighboring pixel electrodes PE is not covered with the pixel electrode PE.

The structure of the pixel electrode PE is not specifically limited, but the pixel electrode PE in the illustrated example has a two-layer structure in which a reflective layer PER and a transmissive layer PET are stacked. The reflective layer PER is disposed on the fourth insulation film 114. The reflective layer PER extends into the contact hole CH, and is electrically connected to the drain electrode D of the switching element SW. The transmissive layer PET is stacked on the reflective layer PER which is disposed immediately above the fourth insulation film 114 and immediately above the contact hole CH.

In the illustrated example, the reflective layer PER and transmissive layer PET are formed with substantially the same size and substantially the same pattern, and the transmissive layer PET is stacked on the entire upper surface of the reflective layer PER. The transmissive layer PET is in contact with neither an upper surface 114T of the fourth insulation film 114 nor a side surface of the reflective layer PER. Although the details will be described later, the position of the side surface of the transmissive layer PET agrees with a position immediately above the side surface of the reflective layer PER, and the side surface of the transmissive layer PET and the side surface of the reflective layer PER form a continuous flat surface or a continuous curved surface.

The reflective layer PER is formed of a light-reflective electrically conductive material, such as silver (Ag) or aluminum (Al). The transmissive layer PET is formed of an electrically conductive material, such as an oxide conductive material, with light transmissivity, like indium tin oxide (ITO) or indium zinc oxide (IZO).

The pixel electrode PE may have a single-layer structure of a reflective layer or a transmissive layer, or may have a multilayer structure of three or more layers. In the case where each of the first to third organic EL element OLED1 to OLED3 is of a top emission type which emits light from the counter-substrate 200 side, the pixel electrode PE includes at least the reflective layer PER. In the case where each of the first to third organic EL element OLED1 to OLED3 is of a bottom emission type which emits light from the insulative substrate 101 side, the pixel electrode PE does not include the reflective layer PER.

An organic layer ORG, which constitutes the first to third organic EL elements OLED1 to OLED3, is disposed on each pixel electrode PE. The organic layer ORG is a continuous film which extends over almost the entirety of the active area 102, and the organic layer ORG extends over the first to third organic EL elements OLED1 to OLED3. Specifically, the organic layer ORG covers the pixel electrodes PE and the fourth insulation film 114 between the pixel electrodes PE.

To be more specific, the organic layer ORG is in contact with the entirety of an upper surface PT of each pixel electrode PE (in particular, an upper surface of the transmissive layer PET in this example), which is located immediately above the fourth insulation film 114 and immediately above the contact hole CH, and the entirety of side surfaces PS of each pixel electrode PE (side surfaces of the reflective layer PER and transmissive layer PET in this example). In addition, the organic layer ORG is in contact with an upper surface 114T of the fourth insulation film 114 between the neighboring pixel electrodes PE.

The organic layer ORG includes at least a light emission layer (not shown). The organic layer ORG may further includes a hole injection layer, a hole transport layer, an electron injection layer, and an electron transport layer. The light emission layer, which constitutes the organic layer ORG, may be formed of a fluorescent material or a phosphorescent material. Although the term “organic layer” is used, at least a part of the light emission layer, hole injection layer, hole transport layer, electron injection layer and electron transport layer may be formed of an inorganic material.

A counter-electrode CE, which constitutes the first to third organic EL elements OLED1 to OLED3, is disposed on the organic layer ORG. In this example, the counter-electrode CE corresponds to a cathode. The counter-electrode CE is a continuous film which extends over almost the entirety of the active area 102, and the counter-electrode CE extends over the first to third organic EL elements OLED1 to OLED3 and covers the organic layer ORG.

The counter-electrode CE is composed of, for example, a semi-transmissive layer. The semi-transmissive layer is formed of, e.g. magnesium (Mg)-silver (Ag). The counter-electrode CE may have a two-layer structure in which a semi-transmissive layer and a transmissive layer are stacked, or may have a single-layer structure of a transmissive layer or a semi-transmissive layer. The transmissive layer may be formed of a light-transmissive electrically conductive material, such as ITO or IZO. In the case where each of the first to third organic EL elements OLED1 to OLED3 is of a bottom emission type which emits light from the insulative substrate 101 side, the counter-electrode CE includes at least a reflective layer or a semi-transmissive layer.

The counter-substrate 200 is disposed above the first to third organic EL elements OLED1 to OLED3 which are formed on the array substrate 100. The counter-substrate 200 is a light-transmissive, insulative substrate such as a glass substrate or a plastic substrate.

In the example illustrated, the array substrate 100 and counter-substrate 200 are separated, and a space is formed therebetween. Alternatively, a protection film or a resin layer, which covers the first to third organic EL elements OLED1 to OLED3, may be disposed between the array substrate 100 and counter-substrate 200. The protection film is formed of an insulating material which has light transmissivity and is hardly permeable to moisture, for instance, an inorganic compound such as silicon nitride or silicon oxynitride. The protection film functions as a moisture barrier film which covers the first to third organic EL elements OLED1 to OLED3, and prevents permeation of moisture into the first to third organic EL elements OLED1 to OLED3. The resin layer is formed of a light-transmissive organic compound such as a thermosetting resin or ultraviolet-curing resin. The resin layer functions as a filling layer which is filled between the array substrate 100 and the counter-substrate 200, or an adhesive layer which bonds the array substrate 100 and the counter-substrate 200. Preferably, the above-described protection film should be interposed between the first to third organic EL elements OLED1 to OLED3 and the resin layer.

In the present embodiment, although the organic layer ORG including the light emission layer is a continuous film extending over the first to third organic EL elements OLED1 to OLED3, the first to third organic EL elements OLED1 to OLED3 are configured to have different emission light colors. In this example, the emission light color of the first organic EL element OLED1 is red, the emission light color of the second organic EL element OLED2 is green, and the emission light color of the third organic EL element OLED3 is blue.

In this example, the range of a major wavelength between 595 nm and 800 nm is defined as a first wavelength range, and the color in the first wavelength range is set to be red. The range of a major wavelength, which is greater than 490 nm and less than 595 nm, is defined as a second wavelength range, and the color in the second wavelength range is set to be green. The range of a major wavelength between 400 nm to 490 nm is defined as a third wavelength range, and the color in the third wavelength range is set to be blue.

The above-described structure may be realized, for example, by the following structure. Specifically, the organic layer ORG of the first to third organic EL elements OLED1 to OLED3 includes, for example, a first dopant material whose emission light color is red, a second dopant material whose emission light color is green, and a third dopant material whose emission light color is blue. In the first organic EL element OLED1, the first dopant material emits light in red. In the second organic EL element OLED2, the first dopant material is quenched, and the second dopant material emits light in green. In the third organic EL element OLED3, the first dopant material and second dopant material are quenched, and the third dopant material emits light in blue.

The form of the organic layer ORG is not specifically limited. The organic layer ORG may have a three-layer structure in which a first light emission layer including the first dopant material, a second light emission layer including the second dopant material and a third light emission layer including the third dopant material are stacked, a two-layer structure in which the first light emission layer and second light emission layer are stacked, or a single-layer structure comprising only the first light emission layer. In the case of the two-layer structure, the first light emission layer may include not only the first dopant material but also the second dopant material and third dopant material, and the second light emission layer may include not only the second dopant material but also the first dopant material and third dopant material. In the case of the single-layer structure, the first light emission layer may include the first dopant material, second dopant material and third dopant material.

As regards the above-described first to third dopant materials, the material in which optical quenching occurs is employed as the material whose light emission capability is varied by light irradiation. However, the materials which are applicable are not limited to the materials in which optical quenching occurs, and it is possible to apply materials whose light emission capabilities are varied by irradiation of, e.g. ultraviolet, for example, whose emission light colors are varied by irradiation of, e.g. ultraviolet.

For example, it is possible to apply materials in which three-dimensional structures of molecules are varied by light irradiation, and thereby emission light colors are varied or light emission is quenched. For instance, the case in which one dopant material is an isomer of the other dopant material corresponds to this example. A cis-configuration and a trans-configuration will now be described in brief as examples of this isomer. The cis-configuration refers to a molecular three-dimensional structure in which two side chains (or atomic groups) are positioned on the same side, relative to a main skeleton. The trans-configuration refers to a molecular three-dimensional structure in which two side chains (or atomic groups) are positioned on opposite sides, relative to a main skeleton. Such a dopant material is selected from materials which are changed, when irradiated with, e.g. ultraviolet, from the cis-configuration to the trans-configuration, or from the trans-configuration to the cis-configuration. An example of such materials is a photochromic material.

Other examples of the isomer include materials which are called photoswitchable proteins or fluorescent proteins. For example, fluorescent proteins include a material which is activated by ultraviolet irradiation from a quenched state and emits light, and a material whose light emission wavelength is changed to another light emission wavelength by ultraviolet irradiation. These fluorescent proteins are applicable as dopant materials in the embodiment.

Besides, it is possible to apply a material in which a dopant material included in a light emission layer is chemically bonded to an additive or a host material, and thereby the emission light color is changed or light emission is quenched.

The display panel 1 in the embodiment adopts such a structure that partition walls for dividing the first to third organic EL elements OLED1 to OLED3 are omitted.

Next, a description is given of the positional relationship between the pixel electrodes PE of the first to third organic EL elements OLED1 to OLED3 and the contact holes CH in the embodiment shown in FIG. 1.

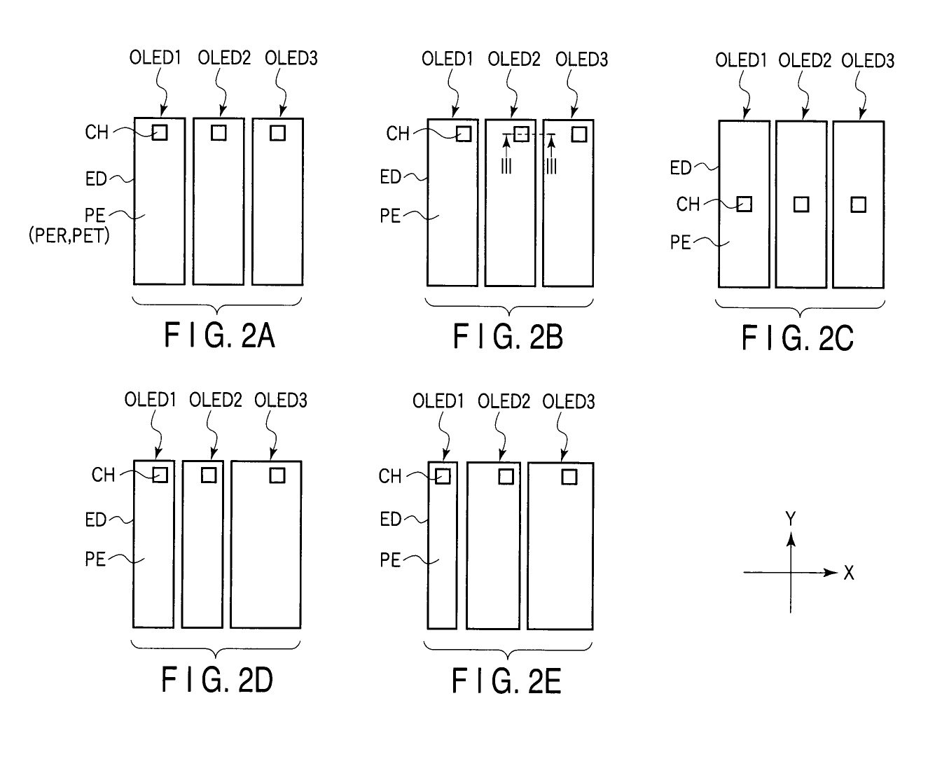

FIGS. 2A, 2B, 2C, 2D and 2E are top views of the first to third organic EL elements OLED1 to OLED3 shown in FIG. 1. In these Figures, depiction of the organic layer ORG and counter-electrode CE is omitted since these are common layers in the first to third organic EL elements OLED1 to OLED3, and only the pixel electrodes PE and the contact holes CH are shown.

The first to third organic EL elements OLED1 to OLED3 have basically the same structure and are arranged in an X direction. The pixel electrodes PE of the first to third organic EL elements OLED1 to OLED3 are disposed, spaced apart from one another. Each pixel electrode PE is formed in a substantially rectangular shape which is elongated in a Y direction, and has a substantially rectangular edge ED. In the illustrated examples, the reflective layer PER and transmissive layer PET, which constitute the pixel electrode PE, have substantially the same size and pattern, as described above, and overlap each other without displacement in the XY plane.

The contact hole CH penetrates to the switching element SW (not shown). The contact hole CH is located inside the edge ED of the pixel electrode PE, and is covered with the pixel electrode PE. In the illustrated example, the contact hole CH has a square shape, but the shape of the contact hole CH is not limited to this example.

In the example shown in FIG. 2A, the contact hole CH is located at a position which is near an end portion in the Y direction of the pixel electrode PE, and near a substantially central portion in the X direction of the pixel electrode PE. In the example shown in FIG. 2B, the contact hole CH is located at a position which is near an end portion in the Y direction of the pixel electrode PE, and near an end portion in the X direction of the pixel electrode PE, or in other words, at a corner portion of the pixel electrode PE. In the example shown in FIG. 2C, the contact hole CH is located at a position which is near a substantially central portion in the Y direction of the pixel electrode PE, and near a substantially central portion in the X direction of the pixel electrode PE, or in other words, at a substantially central portion of the pixel electrode PE. In the examples shown in FIG. 2A, FIG. 2B and FIG. 2C, the pixel electrodes PE of the first to third organic EL elements OLED1 to OLED3 have the same size and are equal in length in the X direction and Y direction.

In the example shown in FIG. 2D, the contact hole CH is located near a corner portion of the pixel electrode PE. However, the example shown in FIG. 2D differs from the example shown in FIG. 2B in that the pixel electrodes PE of the first organic EL element OLED1 and second organic EL element OLED2 have the same size and the pixel electrode PE of the third organic EL element OLED3 is larger than the pixel electrode PE of each of the first organic EL element OLED1 and second organic EL element OLED2. The pixel electrodes PE of the first to third organic EL elements OLED1 to OLED3 are equal in length in the Y direction, and the length in the X direction of the pixel electrode PE of the third organic EL element OLED3 is greater than the length in the X direction of the pixel electrode PE of each of the first organic EL element OLED1 and the second organic EL element OLED2.

Even in the case where the pixel electrode PE of the third organic EL element OLED3 is larger than the pixel electrode PE of each of the first organic EL element OLED1 and second organic EL element OLED2, as shown in FIG. 2D, the contact holes CH may be formed at the same positions as in the examples shown in FIG. 2A and FIG. 2C.

In the example shown in FIG. 2E, the contact hole CH is located near a corner portion of the pixel electrode PE. However, the example shown in FIG. 2E differs from the example shown in FIG. 2B in that the pixel electrode PE of the second organic EL element OLED2 is larger than the pixel electrode PE of the first organic EL element OLED1, and the pixel electrode PE of the third organic EL element OLED3 is larger than the pixel electrode PE of the second organic EL element OLED2. The pixel electrodes PE of the first to third organic EL elements OLED1 to OLED3 are equal in length in the Y direction. The length in the X direction of the pixel electrode PE of the second organic EL element OLED2 is greater than the length in the X direction of the pixel electrode PE the first organic EL element OLED1, and the length in the X direction of the pixel electrode PE of the third organic EL element OLED3 is greater than the length in the X direction of the pixel electrode PE of the second organic EL element OLED2.

Even in the case where the pixel electrode PE of the second organic EL element OLED2 is larger than the pixel electrode PE of the first organic EL element OLED1, and the pixel electrode PE of the third organic EL element OLED3 is larger than the pixel electrode PE of the second organic EL element OLED2, as shown in FIG. 2E, the contact holes CH may be formed at the same positions as in the examples shown in FIG. 2A and FIG. 2C.

Next, a taper angle θ of the contact hole CH in the embodiment is described.

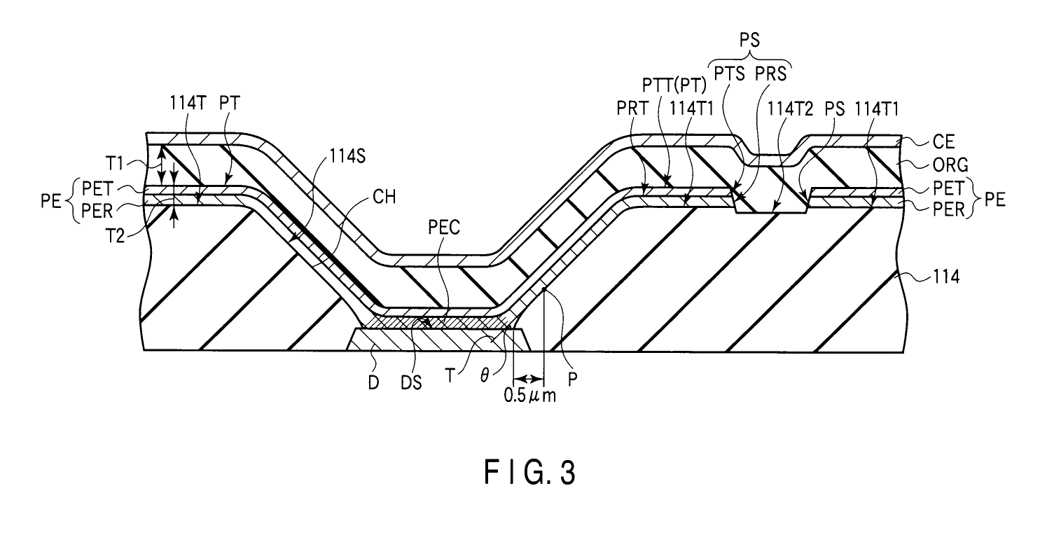

FIG. 3 is a cross-sectional view which schematically shows a cross-sectional structure of the second organic EL element OLED2, taken along line III-III in FIG. 2B. FIG. 3 shows only the main part which is necessary for the description.

The fourth insulation film 114 between the drain electrode D of the switching element and the pixel electrode PE has a substantially flat upper surface 114T. The upper surface 114T includes a first upper surface 114T1 on which the respective pixel electrodes PE are disposed, and an upper surface of the fourth insulation film 114 which is located in the neighborhood of the pixel electrode PE, that is, a second upper surface 114T2 of the fourth insulation film 114 which is located between the neighboring pixel electrodes PE. The contact hole CH, which penetrates to the drain electrode D, is formed in the fourth insulation film 114. A side surface 114S of the fourth insulation film 114 may be either a gently inclined flat surface or a curved surface.

The reflective layer PER, which is disposed on the first upper surface 114T1 of the fourth insulation film 114, extends into the contact hole CH, covers the side surface 1145 of the fourth insulation film 114, and comes in contact with the drain electrode D which is located at the bottom of the contact hole CH. That part of the reflective layer PER, which is in contact with the drain electrode D, corresponds to a contact portion PEC of the pixel electrode PE. The reflective layer PER has an upper surface PRT and a side surface PRS.

The transmissive layer PET is stacked on the upper surface PRT of the reflective layer PER. The transmissive layer PET neither covers the side surface PRS of the reflective layer PER, nor comes in contact with the fourth insulation film 114. The transmissive layer PET has an upper surface PTT and a side surface PTS. The side surface PRS of the reflective layer PER and the side surface PTS of the transmissive layer PET are substantially stepless continuous surfaces, and may be either flat surfaces or curved surfaces.

Although the details will be described later, the pixel electrode PE having the two-layer multiplayer structure can be formed by forming a reflective conductive layer on the fourth insulation film 114, stacking a transmissive conductive layer on the reflective conductive layer, and etching batchwise the reflective conductive layer and transmissive conductive layer. At this time, in the case where dry etching is applied as etching for removing parts of the reflective conductive layer and transmissive conductive layer, it is possible, in some cases, that the surface of the fourth insulation film 114, which is the underlayer of the reflective conductive layer, is removed when the reflective conductive layer and transmissive conductive layer are removed. When wet etching is applied as the etching, the surface of the fourth insulation film 114 is hardly removed.

Thus, of the upper surface 114T of the fourth insulation film 114, the first upper surfaces 114T1, on which the pixel electrodes PE are disposed, have substantially the same position and form the same flat surface, while the second upper surfaces 114T2, which are located between the pixel electrodes PE, are, in some cases, recessed from the first upper surfaces 114T1.

The organic layer ORG is disposed on the upper surface PTT of the transmissive layer PET, which is the upper surface PT of the pixel electrode PE, covers the side surface PRS of the reflective layer PER and the side surface PTS of the transmissive layer PET, which are the side surface PS of the pixel electrode PE, and covers the second upper surface 114T2 which is a part of the upper surface 114T of the fourth insulation film 114 between the pixel electrodes PE.

Preferably, a film thickness T1 of the organic layer ORG should be greater than a film thickness T2 of the pixel electrode PE. The film thickness T1 of the organic layer ORG is the total thickness of the organic layer ORG which is interposed between the pixel electrode PE and the counter-electrode CE. The film thickness T2 of the pixel electrode PE is the total thickness of the film thickness of the reflective layer PER and the film thickness of the transmissive layer PET. Thereby, it is possible to prevent such a defect that a part of the organic layer ORG becomes discontinuous due to a step between the upper surface PT of the pixel electrode PE and the upper surface 114T of the fourth insulation film 114, and to suppress short-circuit between the pixel electrode PE and the counter-electrode CE. For example, when the film thickness of the reflective layer PER is 100 nm and the film thickness of the transmissive layer PET is 25 nm, the film thickness T1 of the pixel electrode PE is 125 nm, while the film thickness T2 of the organic layer ORG is 200 nm.

The counter-electrode CE is disposed on the organic layer ORG which is located immediately above the pixel electrodes PE and immediately above the fourth insulation film 114 between the pixel electrodes PE.

In the present embodiment, the taper angle θ of the contact hole CH is defined as explained below. Although the contact hole CH is formed by removing a part of the fourth insulation film 114, it is difficult to stabilize the shape of the side surface 114S which reaches a surface DS of the drain electrode D. Thus, in the illustrated cross section, the angle between a tangent T at a position P of the side surface 114S, which is distant by 0.5 μm from an intersection between the side surface 114S and the drain electrode D, and the surface DS of the drain electrode D, is defined as the taper angle θ.

In the present embodiment, it is desirable that the taper angle θ be 40° or less. In the case of the contact hole CH which is formed by the steep side surface 114S with the taper angle θ of more than 40°, when the organic layer ORG is formed, a part of the organic layer ORG may become discontinuous. If the counter-electrode CE is formed subsequently on the organic layer ORG, there is a concern that the counter-electrode CE and the pixel electrode PE are short-circuited at the discontinuous part of the organic layer ORG, and the organic EL element fails to normally emit light. Thus, by setting the taper angle θ at 40° or less, the inclination of the side surface 114S becomes gentle, and discontinuity of the organic layer ORG can be suppressed. Hence, short-circuit between the counter-electrode CE and the pixel electrode PE is suppressed, and the organic EL element can be made to normally emit light.

Although the details will be described later, the fourth insulation film 114, in which the contact hole CH with the taper angle θ is formed, can be formed, for example, by coating an insulative film material for forming the fourth insulation film 114, and then performing a patterning for removing the insulative film material at the location where the contact hole CH is to be formed, baking the insulative film material and cooling the insulative film material. In particular, the temperature at the time of baking the insulative film material is set at a temperature at which the insulative film material transitions to a molten state.

Thereby, the insulative film material contracts by the surface tension, like a water drop. After the temperature of the insulative film material is gradually lowered in cooling, the contracted state is retained, and the contact hole CH with the gentle taper angle θ is formed.

According to the embodiment, since partition walls for dividing the first to third organic EL elements OLED1 to OLED3 are omitted, the fabrication step of forming the partition walls is needless, compared to the structure in which partition walls are formed of a resin material in a lattice shape, and the productivity can be enhanced.

According to the embodiment, the organic layer ORG overlaps the entirety of the pixel electrode PE including the peripheral part of the pixel electrode PE and the part immediately above the contract hole CH. Further, the counter-electrode CE is disposed on the organic layer ORG. Thus, almost the entirety of the pixel electrode PE becomes the region which contributes to the emission of light. Therefore, compared to the structure in which partition walls are formed so as to overlap parts of peripheries of the pixel electrodes PE, the area (or opening ratio) of the region which contributes to light emission can be improved.

In the examples shown in FIG. 2A, FIG. 2B, FIG. 2C, FIG. 2D and FIG. 2E, the product of the length in the X direction of the pixel electrode PE and the length in the Y direction of the pixel electrode PE is the area of the region which contributes to light emission. As regards the pixel electrode PE in the region which contributes to light emission, the ratio of the area at the position immediately above the substantially flat first top surface 114T1 of the fourth insulation film 114 is set to be sufficiently greater than the ratio of the area at the position immediately above the contact hole CH. Thereby, an error in chromaticity at a time of observation in the frontal direction, that is, in the normal direction of the display panel 1, can be relaxed. According to the inventor's experiments, it was confirmed that in the case where the ratio of the area located immediately above the contact hole CH, to the area of the region contributing to light emission, is about 15% (i.e. in the case where the ratio of the area located immediately above the first upper surface 114T1 is about 85%), an error in chromaticity hardly occurs.

According to the embodiment, although the organic layer ORG is the continuous film extending over the first to third organic EL elements OLED1 to OLED3, the first to third organic EL elements OLED1 to OLED3 are configured to emit lights of different colors. According to this structure, a metallic fine mask for selectively applying light emission layers is needless, and there is no need to provide a partition wall which functions as a receiving member for supporting such a fine mask, or a partition wall for preventing mixing of colors at a time of selectively applying the light emission layers. Furthermore, it is possible to suppress the occurrence of damage to the surface of the array substrate 100 due to contact with the fine mask.

In the embodiment, according to the structure of FIG. 2A, FIG. 2B, FIG. 2C, FIG. 2D and FIG. 2E, the reflective layer PER and transmissive layer PET, which constitute the pixel electrode PE, are formed by batchwise etching. Thus, compared to the case of forming the reflective layer PER and transmissive layer PET by separately etching them, the number of fabrication steps for forming the array substrate 100 can be reduced, and the productivity can further be improved.

In the examples shown in FIG. 2A, FIG. 2B, FIG. 2C, FIG. 2D and FIG. 2E, only the fourth insulation film 114 is disposed between the switching element SW and the pixel electrode PE. However, an insulation film, which is formed of an inorganic compound and functions as a passivation film, may be additionally disposed between the fourth insulation film 114 and the switching element SW.

In the present embodiment, the description has been given of the case where the pixel electrode PE has the two-layer multilayer structure comprising the reflective layer PER stacked on the fourth insulation film 114 and the transmissive layer PET stacked on the reflective layer PER. In this case, the reflective layer PER can be formed of aluminum or silver, but it is preferable to form the reflective layer PER of aluminum which has higher adhesion properties to the resin-made fourth insulation film 114 than silver, and can make the upper surface PRT of the reflective layer PER smoother than silver.

Next, another structure example of the embodiment is described.

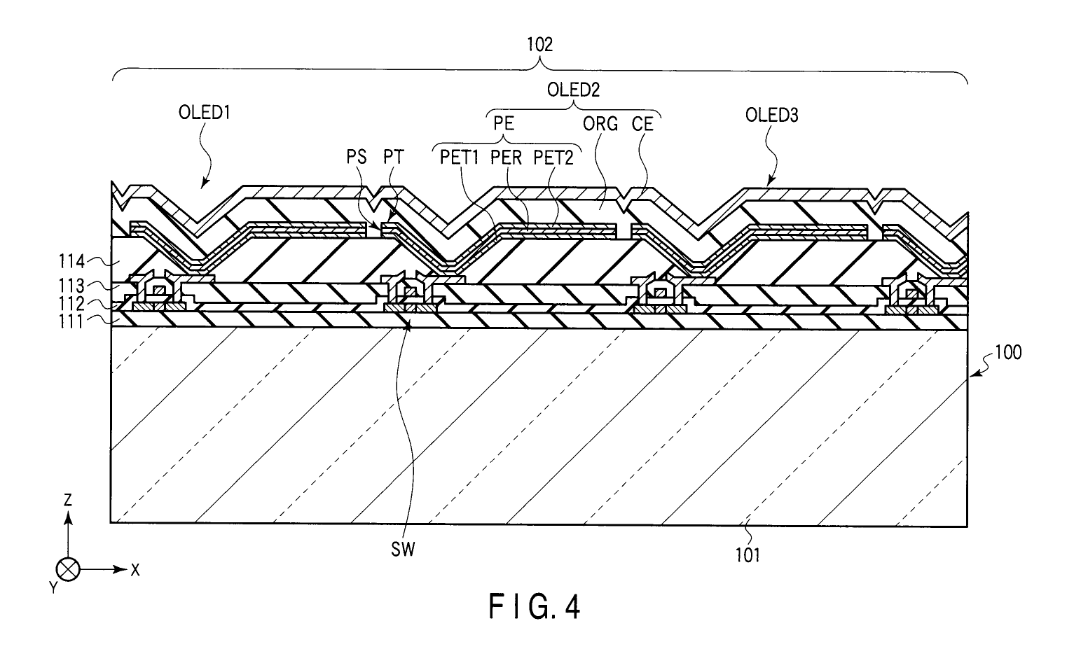

FIG. 4 is a cross-sectional view of an array substrate 100 including switching elements SW and first to third organic EL elements OLED1 to OLED3 of an organic EL display device according to another structure example. The structure example shown in FIG. 4 differs from the example shown in FIG. 1 in that the pixel electrode PE has a three-layer multilayer structure. The same structural parts as in the example shown in FIG. 1 are denoted by like reference numerals, and a detailed description is omitted. Since the first to third organic EL elements OLED1 to OLED3 have basically the same structure, a concrete structure is described with reference to the second organic EL element OLED2.

A first insulation film 111, a second insulation film 112, a third insulation film 113, a fourth insulation film 114 and switching elements SW are disposed between an insulative substrate 101 of an array substrate 100 and the first to third organic EL elements OLED1 to OLED3. Contact holes CH, which reach the switching elements SW, are formed in the fourth insulation film 114.

The pixel electrode PE is disposed on the fourth insulation film 114. The pixel electrode PE comprises a first transmissive layer PET1 which is stacked on the fourth insulation film 114, a reflective layer PER which is stacked on the first transmissive layer PET1, and a second transmissive layer PET2 which is stacked on the reflective layer PER. The first transmissive layer PET1 and second transmissive layer PET2 are formed of an electrically conductive material such as ITO or IZO. For example, ITO has higher adhesion properties to the resin-made fourth insulation film 114 than silver (Ag), and can form the first transmissive layer PET1 which is relatively smooth.

In the pixel electrode PE having the three-layer multilayer structure, the reflective layer PER is disposed on the first transmissive layer PET1, and there is no need to consider the adhesion properties of the reflective layer PER to the fourth insulation film 114. Thus, it is possible to form the reflective layer PER of silver (Ag). The reflective layer PER, which is formed of silver on the first transmissive layer PET1, has a smoother surface than the reflective layer PER, which is formed of silver on the fourth insulation film 114. Needless to say, even in the pixel electrode PE having the three-layer multilayer structure, aluminum (Al) may be applied as the material of the reflective layer PER.

The first transmissive layer PET1 extends into the contact hole CH, and is electrically connected to the switching element SW. The reflective layer PER is stacked on almost the entirety of the upper surface of the first transmissive layer PET1 including the region immediately above the contact hole CH. The second transmissive layer PET2 is stacked on almost the entirety of the upper surface of the reflective layer PER including the region immediately above the contact hole CH.

An organic layer ORG is disposed on each pixel electrode PE. The organic layer ORG is a continuous film which extends over almost the entirety of the active area 102, and the organic layer ORG extends over the first to third organic EL elements OLED1 to OLED3. Specifically, the organic layer ORG covers an upper surface PT and a side surface PS of each pixel electrodes PE and also covers the fourth insulation film 114 between the pixel electrodes PE.

A counter-electrode CE is disposed on the organic layer ORG. The counter-electrode CE is a continuous film which extends over almost the entirety of the active area 102, and the counter-electrode CE extends over the first to third organic EL elements OLED1 to OLED3 and covers the organic layer ORG.

With this structure example, too, the same advantageous effects as in the above-described example can be obtained.

Also in this structure example, it is desirable that the film thickness of the organic layer ORG be greater than the film thickness of the pixel electrode PE. For example, the film thickness T1 of the pixel electrode PE of the three-layer multiplayer structure is 175 nm, while the film thickness T2 of the organic layer ORG is 200 nm.

Next, still another structure example of the embodiment is described.

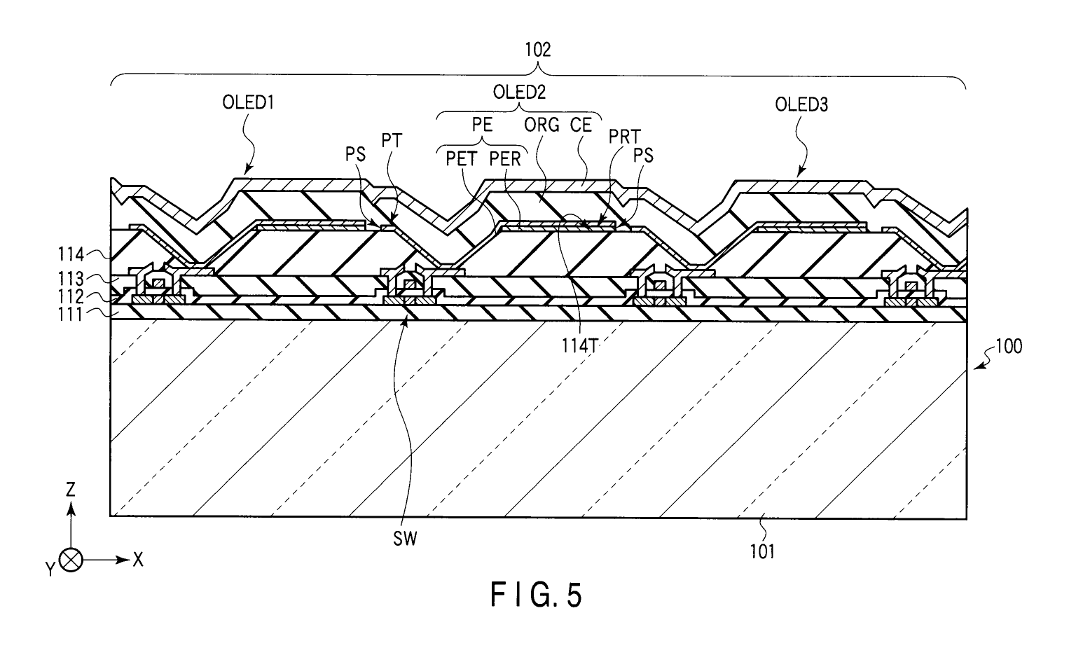

FIG. 5 is a cross-sectional view of an array substrate 100 including switching elements SW and first to third organic EL elements OLED1 to OLED3 of an organic EL display device according to still another structure example. The structure example shown in FIG. 5 differs from the example shown in FIG. 1 in that the reflective layer PER, which constitutes the pixel electrode PE, is missing in the region immediately above the contact hole CH and in the neighborhood of the contact hole CH. The same structural parts as in the example shown in FIG. 1 are denoted by like reference numerals, and a detailed description is omitted. Since the first to third organic EL elements OLED1 to OLED3 have basically the same structure, a concrete structure is described with reference to the second organic EL element OLED2.

A first insulation film 111, a second insulation film 112, a third insulation film 113, a fourth insulation film 114 and switching elements SW are disposed between an insulative substrate 101 of an array substrate 100 and the first to third organic EL elements OLED1 to OLED3. Contact holes CH, which reach the switching elements SW, are formed in the fourth insulation film 114.

The pixel electrode PE is disposed on the fourth insulation film 114. The pixel electrode PE comprises a reflective layer PER which is stacked on the fourth insulation film 114, and a transmissive layer PET which is stacked on the upper surface PRT of the reflective layer PER. The reflective layer PER is disposed on a substantially flat first upper surface 114T1 of the fourth insulation film 114, and does not extend to the contact hole CH. The transmissive layer PET extends from above the reflective layer PER into the contact hole CH, and is electrically connected to the switching element SW.

An organic layer ORG is disposed on each pixel electrode PE. The organic layer ORG is a continuous film which extends over almost the entirety of the active area 102, and the organic layer ORG extends over the first to third organic EL elements OLED1 to OLED3. Specifically, the organic layer ORG covers an upper surface PT of each pixel electrode PE (an upper surface of the transmissive layer PET in this example) and a side surface of each pixel electrode PE (side faces of the reflective layer PER and transmissive layer PET in this example), and also covers the fourth insulation film 114 between the pixel electrodes PE.

A counter-electrode CE is disposed on the organic layer ORG. The counter-electrode CE is a continuous film which extends over almost the entirety of the active area 102, and the counter-electrode CE extends over the first to third organic EL elements OLED1 to OLED3 and covers the organic layer ORG.

Next, a description is given of the positional relationship between the pixel electrodes PE of the first to third organic EL elements OLED1 to OLED3 and the contact holes CH in the structure example shown in FIG. 5.

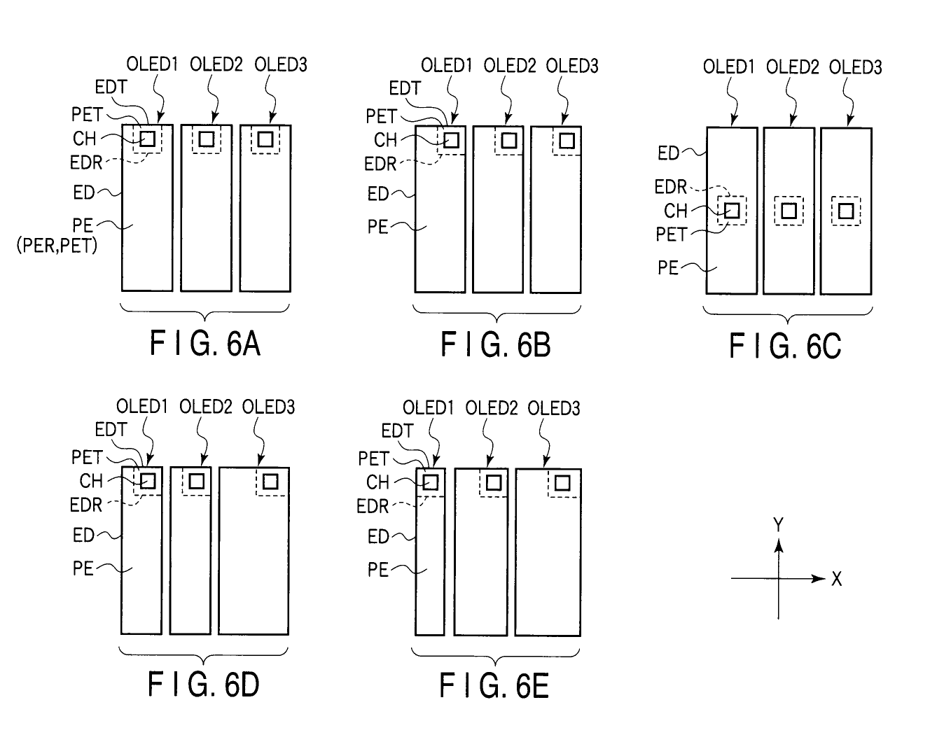

FIGS. 6A, 6B, 6C, 6D and 6E are top views of the first to third organic EL elements OLED1 to OLED3 shown in FIG. 5. In these Figures, depiction of the organic layer ORG and counter-electrode CE is omitted since these are common layers in the first to third organic EL elements OLED1 to OLED3, and only the pixel electrodes PE and the contact holes CH are shown.

The first to third organic EL elements OLED1 to OLED3 have basically the same structure and are arranged in an X direction. The pixel electrodes PE of the first to third organic EL elements OLED1 to OLED3 are disposed, spaced apart from one another. Each pixel electrode PE is formed in a substantially rectangular shape which is elongated in a Y direction, and has a substantially rectangular edge ED. The pixel electrode PE in the illustrated example differs from the pixel electrode PE which is formed by batch etching, as shown in FIGS. 2A, 2B, 2C, 2D and 2E. Specifically, the reflective layer PER and transmissive layer PET, which constitute the pixel electrode PE shown in FIG. 6A, FIG. 6B, FIG. 6C, FIG. 6D and FIG. 6E, have different sizes and patterns. The edge ED includes an edge EDR which is formed by the side surface of the reflective layer PER, and an edge EDT which is formed by the side surface of the transmissive layer PET.

The contact hole CH penetrates to the switching element SW (not shown). The contact hole CH is located inside the edge ED of the pixel electrode PE (the edge EDT of the transmissive layer PET in this example), and is covered with the pixel electrode PE. In the illustrated example, the contact hole CH has a square shape, but the shape of the contact hole CH is not limited to this example.

The reflective layer PER is missing in the contact hole CH and in the neighborhood of the contact hole CH. The transmissive layer PET covers the reflective layer PER and contact hole CH. The reflective layer PER and the transmissive layer PET are formed by different patterning steps. In the illustrated example, the edge EDR of the reflective layer PER and the edge EDT of the transmissive layer PET overlap, except the region of the contact hole CH and the peripheral part thereof.

In the example shown in FIG. 6A, the contact hole CH is located at a position which is near an end portion in the Y direction of the pixel electrode PE, and near a substantially central portion in the X direction of the pixel electrode PE. In this case, the edge EDR of the reflective layer PER in the vicinity of the contact hole CH has a substantially U shape. In the example shown in FIG. 6B, the contact hole CH is located at a position which is near an end portion in the Y direction of the pixel electrode PE, and near an end portion in the X direction of the pixel electrode PE, or in other words, at a corner portion of the pixel electrode PE. In this case, the edge EDR of the reflective layer PER in the vicinity of the contact hole CH has a substantially L shape. In the example shown in FIG. 6C, the contact hole CH is located at a position which is near a substantially central portion in the Y direction of the pixel electrode PE, and near a substantially central portion in the X direction of the pixel electrode PE, or in other words, at a substantially central portion of the pixel electrode PE. In this case, the edge EDR of the reflective layer PER in the vicinity of the contact hole CH has a substantially square shape. In the examples shown in FIG. 6A, FIG. 6B and FIG. 6C, the pixel electrodes PE of the first to third organic EL elements OLED1 to OLED3 have the same size and are equal in length in the X direction and Y direction.

In the example shown in FIG. 6D, the contact hole CH is located near a corner portion of the pixel electrode PE. However, the example shown in FIG. 6D differs from the example shown in FIG. 6B in that the pixel electrodes PE of the first organic EL element OLED1 and second organic EL element OLED2 have the same size and the pixel electrode PE of the third organic EL element OLED3 is larger than the pixel electrode PE of each of the first organic EL element OLED1 and second organic EL element OLED2. The pixel electrodes PE of the first to third organic EL elements OLED1 to OLED3 are equal in length in the Y direction, and the length in the X direction of the pixel electrode PE of the third organic EL element OLED3 is greater than the length in the X direction of the pixel electrode PE of each of the first organic EL element OLED1 and the second organic EL element OLED2. In this case, the edge EDR of the reflective layer PER in the vicinity of the contact hole CH has a substantially L shape, and is covered with the transmissive layer PET.

Even in the case where the pixel electrode PE of the third organic EL element OLED3 is larger than the pixel electrode PE of each of the first organic EL element OLED1 and second organic EL element OLED2, as shown in FIG. 6D, the contact holes CH may be formed at the same positions as in the examples shown in FIG. 6A and FIG. 6C.

In the example shown in FIG. 6E, the contact hole CH is located near a corner portion of the pixel electrode PE. However, the example shown in FIG. 6E differs from the example shown in FIG. 6B in that the pixel electrode PE of the second organic EL element OLED2 is larger than the pixel electrode PE of the first organic EL element OLED1, and the pixel electrode PE of the third organic EL element OLED3 is larger than the pixel electrode PE of the second organic EL element OLED2. The pixel electrodes PE of the first to third organic EL elements OLED1 to OLED3 are equal in length in the Y direction. The length in the X direction of the pixel electrode PE of the second organic EL element OLED2 is greater than the length in the X direction of the pixel electrode PE the first organic EL element OLED1, and the length in the X direction of the pixel electrode PE of the third organic EL element OLED3 is greater than the length in the X direction of the pixel electrode PE of the second organic EL element OLED2. In this case, the edge EDR of the reflective layer PER in the vicinity of the contact hole CH has a substantially L shape or a straight shape, and is covered with the transmissive layer PET.

Even in the case where the pixel electrode PE of the second organic EL element OLED2 is larger than the pixel electrode PE of the first organic EL element OLED1, and the pixel electrode PE of the third organic EL element OLED3 is larger than the pixel electrode PE of the second organic EL element OLED2, as shown in FIG. 6E, the contact holes CH may be formed at the same positions as in the examples shown in FIG. 6A and FIG. 6C.

Also in this structure example, the same advantageous effects as in the above-described example can be obtained.

Compared to the example shown in FIG. 1, since the reflective layer PER of the pixel electrode PE is missing in the vicinity of the contact hole CH, the area contributing to light emission is slightly decreased. However, since there is no influence of reflective light at the inclined side surface 114S of the contact hole CH, the chromaticity can be improved.

Next, still another structure example of the embodiment is described.

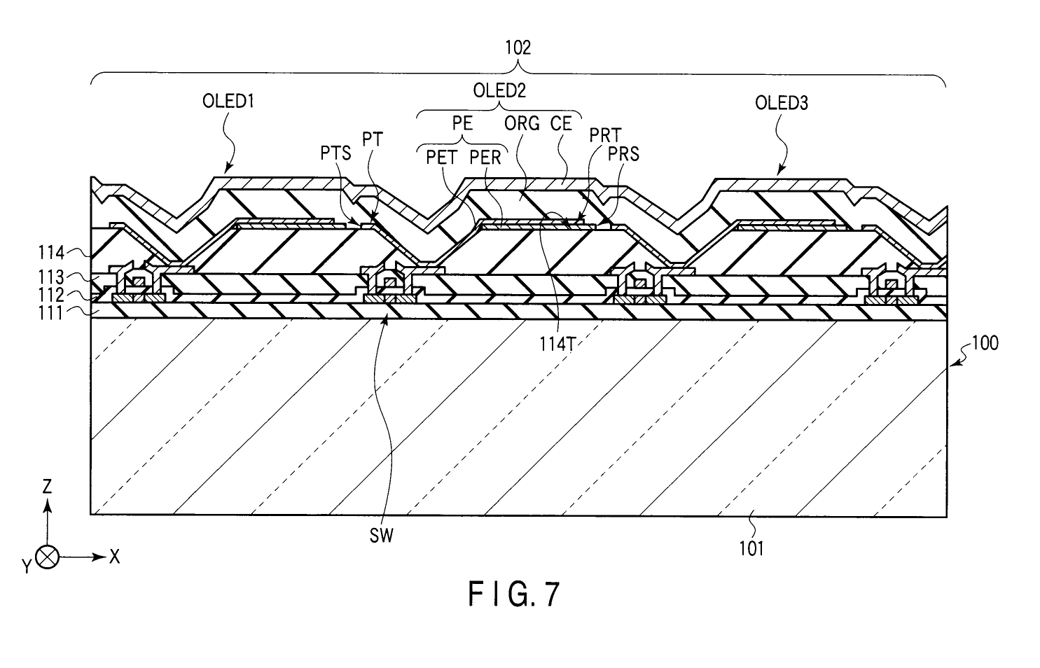

FIG. 7 is a cross-sectional view of an array substrate 100 including switching elements SW and first to third organic EL elements OLED1 to OLED3 of an organic EL display device according to still another structure example. The structure example shown in FIG. 7 differs from the example shown in FIG. 1 in that the reflective layer PER, which constitutes the pixel electrode PE, is missing in the region immediately above the contact hole CH and in the neighborhood of the contact hole CH, and that a part of the side surface of the transmissive layer PET, which is stacked on the upper surface of the reflective layer PER, is located inside the position of the side surface of the reflective layer PER. The same structural parts as in the example shown in FIG. 1 are denoted by like reference numerals, and a detailed description is omitted. Since the first to third organic EL elements OLED1 to OLED3 have basically the same structure, a concrete structure is described with reference to the second organic EL element OLED2.

A first insulation film 111, a second insulation film 112, a third insulation film 113, a fourth insulation film 114 and switching elements SW are disposed between an insulative substrate 101 of an array substrate 100 and the first to third organic EL elements OLED1 to OLED3. Contact holes CH, which reach the switching elements SW, are formed in the fourth insulation film 114.

The pixel electrode PE is disposed on the fourth insulation film 114. The pixel electrode PE comprises a reflective layer PER which is stacked on the fourth insulation film 114, and a transmissive layer PET which is stacked on the upper surface PRT of the reflective layer PER. The reflective layer PER is disposed on a substantially flat first upper surface 114T1 of the fourth insulation film 114, and does not extend to the contact hole CH. The transmissive layer PET extends from the upper surface PRT of the reflective layer PER into the contact hole CH, and is electrically connected to the switching element SW. A part of the side surface PTS of the transmissive layer PET is located inside the position immediately above the side surface PRS of the reflective layer PER.

An organic layer ORG is disposed on each pixel electrode PE. The organic layer ORG is a continuous film which extends over almost the entirety of the active area 102, and the organic layer ORG extends over the first to third organic EL elements OLED1 to OLED3. Specifically, the organic layer ORG covers an upper surface PT of each pixel electrode PE (an upper surface of the transmissive layer PET and a part of an upper surface of the reflective layer PER in this example) and a side surface PS of each pixel electrode PE (side faces of the reflective layer PER and transmissive layer PET in this example), and also covers the fourth insulation film 114 between the pixel electrodes PE.

A counter-electrode CE is disposed on the organic layer ORG. The counter-electrode CE is a continuous film which extends over almost the entirety of the active area 102, and the counter-electrode CE extends over the first to third organic EL elements OLED1 to OLED3 and covers the organic layer ORG.

Next, a description is given of the positional relationship between the pixel electrodes PE of the first to third organic EL elements OLED1 to OLED3 and the contact holes CH in the structure example shown in FIG. 7.

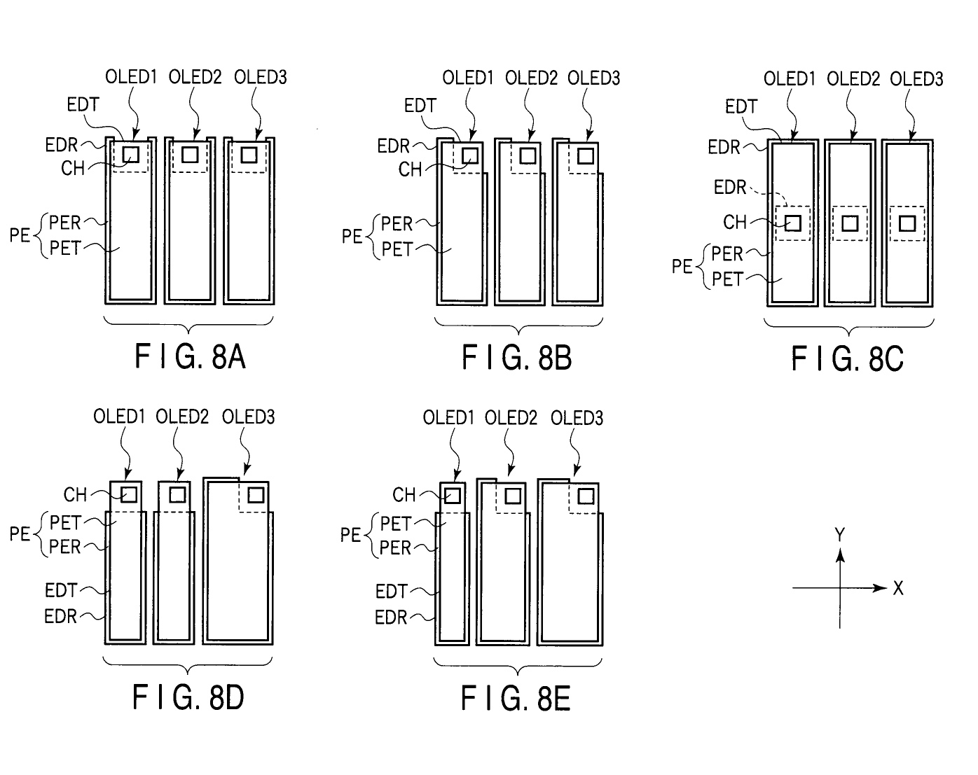

FIGS. 8A, 8B, 8C, 8D and 8E are top views of the first to third organic EL elements OLED1 to OLED3 shown in FIG. 7. In these Figures, depiction of the organic layer ORG and counter-electrode CE is omitted since these are common layers in the first to third organic EL elements OLED1 to OLED3, and only the pixel electrodes PE and the contact holes CH are shown.

The first to third organic EL elements OLED1 to OLED3 have basically the same structure and are arranged in an X direction. The pixel electrodes PE of the first to third organic EL elements OLED1 to OLED3 are disposed, spaced apart from one another. Each pixel electrode PE is formed in a substantially rectangular shape which is elongated in a Y direction, and has a substantially rectangular edge ED. The pixel electrode PE in the illustrated example differs from the pixel electrode PE which is formed by batch etching, as shown in FIGS. 2A, 2B, 2C, 2D and 2E. Specifically, the reflective layer PER and transmissive layer PET, which constitute the pixel electrode PE shown in FIG. 8A, FIG. 8B, FIG. 8C, FIG. 8D and FIG. 8E, have different sizes and patterns. The edge ED includes an edge EDR which is formed by the side surface of the reflective layer PER, and an edge EDT which is formed by the side surface of the transmissive layer PET.

The contact hole CH penetrates to the switching element SW (not shown). The contact hole CH is located inside the edge ED of the pixel electrode PE (the edge EDT of the transmissive layer PET in this example), and is covered with the pixel electrode PE. In the illustrated example, the contact hole CH has a square shape, but the shape of the contact hole CH is not limited to this example.

The reflective layer PER is missing in the contact hole CH and in the neighborhood of the contact hole CH. The transmissive layer PET covers the reflective layer PER and contact hole CH. The reflective layer PER and the transmissive layer PET are formed by different patterning steps. In the illustrated example, the edge EDT of the transmissive layer PET is located inside the edge EDR of the reflective layer PER, except the region of the contact hole CH and the peripheral part thereof.

In the example shown in FIG. 8A, the contact hole CH is located at a position which is near an end portion in the Y direction of the pixel electrode PE, and near a substantially central portion in the X direction of the pixel electrode PE. In this case, the edge EDR of the reflective layer PER in the vicinity of the contact hole CH has a substantially U shape. The substantially U-shaped part of the edge EDR is covered with the transmissive layer PET.

In the example shown in FIG. 8B, the contact hole CH is located at a position which is near an end portion in the Y direction of the pixel electrode PE, and near an end portion in the X direction of the pixel electrode PE, or in other words, at a corner portion of the pixel electrode PE. In this case, the edge EDR of the reflective layer PER in the vicinity of the contact hole CH has a substantially L shape. The substantially L-shaped part of the edge EDR is covered with the transmissive layer PET.

In the example shown in FIG. 8C, the contact hole CH is located at a position which is near a substantially central portion in the Y direction of the pixel electrode PE, and near a substantially central portion in the X direction of the pixel electrode PE, or in other words, at a substantially central portion of the pixel electrode PE. In this case, the edge EDR of the reflective layer PER in the vicinity of the contact hole CH has a substantially square shape. The substantially square part of the edge EDR is covered with the transmissive layer PET.

In the examples shown in FIG. 8A, FIG. 8B and FIG. 8C, the pixel electrodes PE of the first to third organic EL elements OLED1 to OLED3 have the same size and are equal in length in the X direction and Y direction.

In the example shown in FIG. 8D, the contact hole CH is located near a corner portion of the pixel electrode PE. However, the example shown in FIG. 8D differs from the example shown in FIG. 8B in that the pixel electrodes PE of the first organic EL element OLED1 and second organic EL element OLED2 have the same size and the pixel electrode PE of the third organic EL element OLED3 is larger than the pixel electrode PE of each of the first organic EL element OLED1 and second organic EL element OLED2. The pixel electrodes PE of the first to third organic EL elements OLED1 to OLED3 are equal in length in the Y direction, and the length in the X direction of the pixel electrode PE of the third organic EL element OLED3 is greater than the length in the X direction of the pixel electrode PE of each of the first organic EL element OLED1 and the second organic EL element OLED2. In this case, the edge EDR of the reflective layer PER in the vicinity of the contact hole CH has a substantially L shape or a straight shape, and is covered with the transmissive layer PET.

Even in the case where the pixel electrode PE of the third organic EL element OLED3 is larger than the pixel electrode PE of each of the first organic EL element OLED1 and second organic EL element OLED2, as shown in FIG. 8D, the contact holes CH may be formed at the same positions as in the examples shown in FIG. 8A and FIG. 8C.

In the example shown in FIG. 8E, the contact hole CH is located near a corner portion of the pixel electrode PE. However, the example shown in FIG. 8E differs from the example shown in FIG. 8B in that the pixel electrode PE of the second organic EL element OLED2 is larger than the pixel electrode PE of the first organic EL element OLED1, and the pixel electrode PE of the third organic EL element OLED3 is larger than the pixel electrode PE of the second organic EL element OLED2. The pixel electrodes PE of the first to third organic EL elements OLED1 to OLED3 are equal in length in the Y direction. The length in the X direction of the pixel electrode PE of the second organic EL element OLED2 is greater than the length in the X direction of the pixel electrode PE the first organic EL element OLED1, and the length in the X direction of the pixel electrode PE of the third organic EL element OLED3 is greater than the length in the X direction of the pixel electrode PE of the second organic EL element OLED2. In this case, the edge EDR of the reflective layer PER in the vicinity of the contact hole CH has a substantially L shape or a straight shape, and is covered with the transmissive layer PET.

Even in the case where the pixel electrode PE of the second organic EL element OLED2 is larger than the pixel electrode PE of the first organic EL element OLED1, and the pixel electrode PE of the third organic EL element OLED3 is larger than the pixel electrode PE of the second organic EL element OLED2, as shown in FIG. 8E, the contact holes CH may be formed at the same positions as in the examples shown in FIG. 8A and FIG. 8C.

Also in this structure example, the same advantageous effects as in the above-described example can be obtained.

Compared to the example shown in FIG. 5, since the transmissive layer PET of the pixel electrode PE does not project out from the reflective layer PER, except the region in the vicinity of the contact hole CH, light emission of a color different from a desired chromaticity can be reduced, and the chromaticity can further be improved.

As regards the organic EL devices of the above-described embodiment, the aperture ratios in representative layouts of the respective structure examples were compared. It was assumed that the conditions, such as the fineness, inter-pixel pitch and size of contact hole CH in the active area, are the same, and that the aperture ratio in a structure, in which partition walls are formed so as to overlap parts of peripheries of pixel electrodes PE, is set at 100%.

The aperture ratios in the representative layouts of the contact holes and pixel electrodes in the respective structure examples of the embodiment are as follows. In the example shown in FIG. 2A, the aperture ratio was 178%. In the example shown in FIG. 6A, the aperture ratio was 173%. In the example shown in FIG. 8A, the aperture ratio was 135%. According to the present embodiment, compared to the structure including partition walls, such partition walls are omitted. Thus, the organic layer and counter-electrode are disposed on the pixel electrode, which would be covered with the partition walls in the structure including the partition walls, and contribute to light emission. It was confirmed, therefore, that the aperture ratio can be improved.

Next, a method of manufacturing the organic EL device in the embodiment is described.

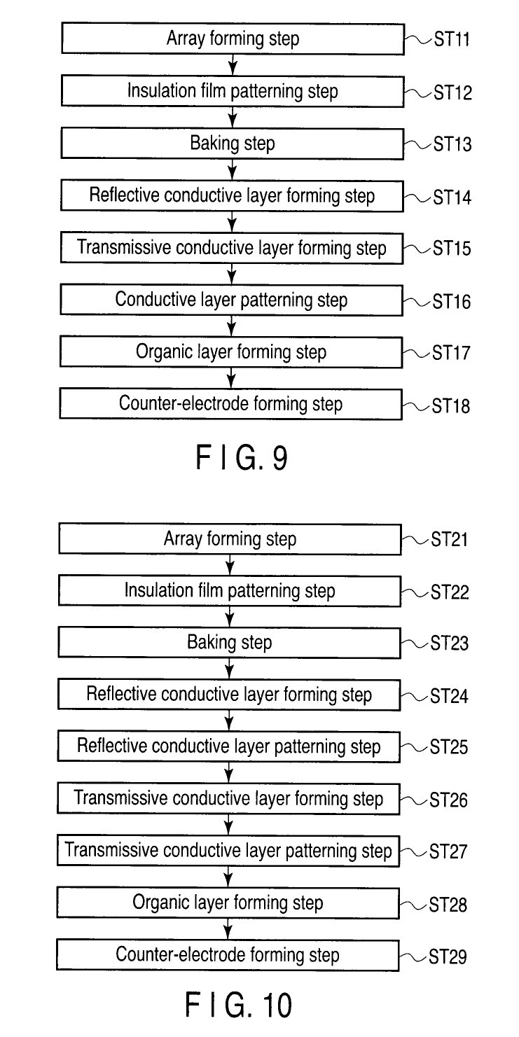

FIG. 9 is a flow chart for describing the method of manufacturing the organic EL device having the structure shown in FIG. 1.

To start with, switching elements SW, etc. are formed above an insulative substrate 101 (ST11). In this step, a first insulation film 111, a second insulation film 112 and a third insulation film 113, as well as the switching elements SW, are formed. This step is referred to as an array forming step.

Subsequently, an insulation film material for forming a fourth insulation film 114 is coated on the switching elements SW, and the insulation film material is patterned to form contact holes CH which reach the switching elements SW (ST12). This step is referred as an insulation film patterning step.

The patterned insulation film material is then baked (ST13). At this time, the temperature for baking the insulation film material is set at a temperature at which the insulation film material transitions to a molten state (i.e. a temperature in the neighborhood of the melting point of the insulation film material). By the baking, a surface portion of the insulation film material deforms to become smooth by the surface tension thereof, and the taper angle of the contact hole CH, which was formed by the patterning, decreases to 40° or less. Then, by gradually lowering the temperature in cooling, the surface shape of the insulation film material is retained. In this manner, the fourth insulation film, in which the contact holes CH are formed, is formed. This step is referred to as a baking step.

Thereafter, a reflective conductive layer is formed on the fourth insulation film 114 and in the contact hole CH (ST14). The reflective conductive layer is formed of aluminum (Al). This step is referred to as a reflective conductive film forming step.

A transmissive conductive layer is stacked on the reflective conductive layer (ST15). The transmissive conductive layer is formed of ITO. This step is referred to as a transmissive conductive layer forming step.

Then, the reflective conductive layer and transmissive conductive layer are patterned (ST16). In this patterning step, for example, a resist is coated on the transmissive conductive layer, and a part of the resist, which lies in the region for forming the pixel electrode PE, is removed through a photolithography process. The transmissive conductive layer, which is exposed from the resist, is removed by etching, and further the reflective conductive layer under the region, where the transmissive conductive layer has been removed, is removed by etching. In this manner, the reflective conductive layer and transmissive conductive layer are etched batchwise. In the region where the reflective conductive layer has been removed, the fourth insulation film 114 is exposed. Then, the remaining resist is peeled, and the pixel electrode PE comprising a reflective layer PER and a transmissive layer PET, which have desired shapes, is formed. This step is referred to as a conductive layer patterning step.

Following the above, an organic layer ORG is formed on the pixel electrode PE and on the fourth insulation film 114 (ST17). This step is referred to as an organic layer forming step.

A counter-electrode CE is formed on the organic layer ORG (ST18). This step is referred to as a counter-electrode forming step.

The array substrate 100 of the display panel 1 as shown in FIG. 1 is formed through the above-described fabrication steps.

In the case of forming the pixel electrode PE of the three-layer multilayer structure as shown in FIG. 4, for example, the above-described step ST14 is replaced with a step of forming a transmissive conductive layer for forming a first transmissive layer PET1 on the fourth insulation film 114, and then forming a reflective conductive layer using silver (Ag), thereby to form a reflective layer PER on the transmissive conductive layer. In this case, in step ST16 shown in FIG. 9, the transmissive conductive layer, which is exposed from the resist, is removed by etching, and then the reflective conductive layer under the region, where the transmissive conductive layer has been removed, is removed by etching, and furthermore the transmissive conductive layer under the region, where the reflective conductive layer has been removed, is removed by etching. In this way, the transmissive conductive layer for forming the first transmissive layer PET1, the reflective conductive layer for forming the reflective layer PER, and the transmissive conductive layer for forming the second transmissive layer PET2 are etched batchwise.

As has been described above, since the step of forming partition walls which overlap peripheries of pixel electrodes is omitted and the pixel electrode PE having the structure in which the reflective layer PER and the transmissive layer PET are stacked is formed by batchwise etching, the number of fabrication steps can be reduced and the productivity can be improved.

FIG. 10 is a flow chart for describing the method of manufacturing the organic EL devices having the structures shown in FIG. 5 and FIG. 7.

An array forming step (ST21) is identical to the array forming step shown in FIG. 9. Similarly, an insulation film patterning step (ST22) is identical to the insulation film patterning step shown in FIG. 9, a baking step (ST23) is identical to the baking step of FIG. 9, and a reflective conductive layer forming step (ST24) is identical to the reflective conductive layer forming step of FIG. 9. A description of these steps is omitted here.

Following the above steps, the reflective conductive layer is patterned (ST25). In this patterning step, for example, a resist is coated on the reflective conductive layer, and a part of the resist, which lies in the region for forming the pixel electrode PE, is removed through a photolithography process. Then, the reflective conductive layer, which is exposed from the resist, is removed by etching. In the region where the reflective conductive layer has been removed, the fourth insulation film 114 is exposed. Then, the remaining resist is peeled, and a reflective layer PER of a desired shape is formed. This step is referred to as a reflective conductive layer patterning step.

A transmissive conductive layer is stacked on the reflective conductive layer and on the fourth insulation film 114 (ST26). The transmissive conductive layer is formed of ITO. This step is referred to as a transmissive conductive layer forming step.

Subsequently, the transmissive conductive layer is patterned (ST27). In this patterning step, for example, a resist is coated on the transmissive conductive layer, and a part of the resist, which lies in the region for forming the pixel electrode PE, is removed through a photolithography process. Then, the transmissive conductive layer, which is exposed from the resist, is removed by etching. In the region where the transmissive conductive layer has been removed, the fourth insulation film 114 is exposed. Then, the remaining resist is peeled, and the pixel electrode PE comprising the reflective layer PER and transmissive layer PET, which have desired shapes, is formed. This step is referred to as a transmissive conductive layer patterning step.

Following the above, an organic layer ORG is formed on the pixel electrode PE and on the fourth insulation film 114 (ST28). This step is referred to as an organic layer forming step.

A counter-electrode CE is formed on the organic layer ORG (ST29). This step is referred to as a counter-electrode forming step.

The array substrate 100, as shown in FIG. 5 and FIG. 7, is formed through the above-described fabrication steps.

In the case of forming the pixel electrode PE of the three-layer multilayer structure as shown in FIG. 4, for example, the above-described step ST24 is replaced with a step of forming a transmissive conductive layer for forming a first transmissive layer PET1 on the fourth insulation film 114, and then forming a reflective conductive layer using silver (Ag), thereby to form a reflective layer PER on the transmissive conductive layer. In this case, in step ST25 shown in FIG. 10, the reflective conductive layer, which is exposed from the resist, is removed by etching, and then the transmissive conductive layer under the region, where the reflective conductive layer has been removed, is removed by etching. In this manner, the transmissive conductive layer for forming the first transmissive layer PET1, and the reflective conductive layer for forming the reflective layer PER are etched batchwise.

As has been described above, since the step of forming partition walls which overlap peripheries of pixel electrodes is omitted, the number of fabrication steps can be reduced and the productivity can be improved.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

The present embodiment has been described with respect to the organic EL display device as the organic EL device, but the invention is applicable to organic EL illumination equipment, an organic EL printer head, etc.

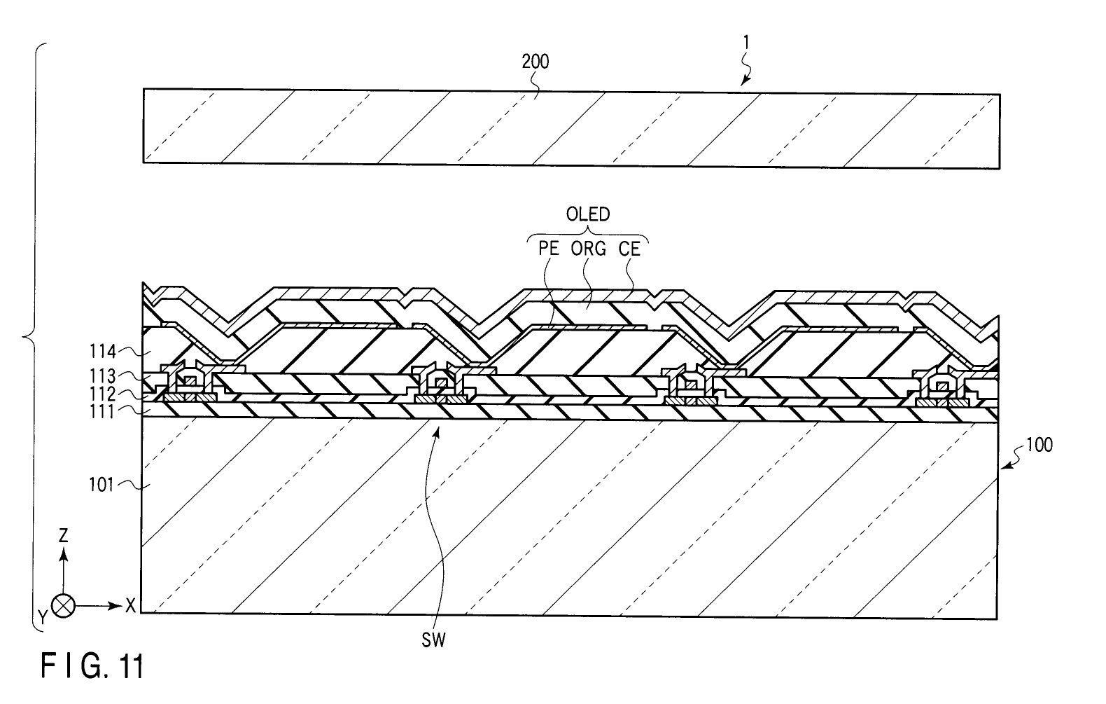

In the embodiment, the case has been described in which the first to third organic EL elements OLED1 to OLED3 are of the top emission type in which the first to third organic EL elements OLED1 to OLED3 include the reflective layers PER. Alternatively, as shown in FIG. 11, use may be made of an organic EL element OLED of a bottom emission type in which the organic EL element OLED comprises a pixel electrode PE which does not include a reflective layer. Although the details are omitted, this organic EL element OLED comprises a pixel electrode PE which is formed of a transmissive layer of ITO or IZO, an organic layer ORG which is disposed on the pixel electrode PE, and a counter-electrode CE which is disposed on the organic layer ORG. With the organic EL element OLED of the bottom emission type, the same advantageous effects as with the above-described top emission type can be obtained.

What is claimed is:

1. An organic EL device comprising:
an insulative substrate;
a switching element above the insulative substrate;
an insulation film above the switching element and comprising a contact hole reaching the switching element;
a pixel electrode above the insulation film and comprising a contact portion extending into the contact hole and electrically connected to the switching element;
an organic layer extending over the pixel electrode including the contact portion, and extending over the insulation film in a vicinity of the pixel electrode; and
a counter-electrode above the organic layer.

2. The organic EL device of claim 1, wherein the pixel electrode includes (a) a reflective layer which has an upper surface and a first side surface, is above the insulation film, and extends into the contact hole, and a transmissive layer on the upper surface of the reflective layer and comprising a second side surface at a position agreeing with a position immediately above the first side surface, or includes (b) a reflective layer which has an upper surface and is above the insulation film, and a transmissive layer
an insulation film;
a pixel electrode above the insulation film and comprising a substantially rectangular edge;
a contact hole in the insulation film, located inside the edge of the pixel electrode, and covered by the pixel electrode;
an organic layer extending over the pixel electrode and over the insulation film in a vicinity of the pixel electrode; and
a counter-electrode above the organic layer.

8. The organic EL device of claim 7, wherein the pixel electrode includes (a) a reflective layer which has an upper surface and a first side surface, is above the insulation film, and extends into the contact hole, and a transmissive layer on the upper surface of the reflective layer and comprising a second side surface at a position agreeing with a position immediately above the first side surface, or includes (b) a reflective layer which has an upper surface and is above the insulation film, and a transmissive layer which is on the upper surface of the reflective layer and extends into the contact hole, or includes (c) a reflective layer which has an upper surface and a first side surface, and is above the insulation film, and a transmissive layer which is on the upper surface of the reflective layer, has a second side surface at a part of a position inside a position immediately above the first side surface, and extends into the contact hole.

9. The organic EL device of claim 8, wherein the insulation film comprises a first upper surface on which the pixel electrode is disposed, and a second upper surface which is located in a vicinity of the pixel electrode and is recessed from the first upper surface.

10. The organic EL device of claim 7, wherein the insulation film comprises a first upper surface on which the pixel electrode is disposed, and a second upper surface which is located in a vicinity of the pixel electrode and is recessed from the first upper surface.

11. The organic EL device of claim 7, wherein a taper angle of the contact hole in the insulation film is 40° or less.

12. The organic EL device of claim 7, wherein a film thickness of the organic layer is greater than a film thickness of the pixel electrode.

13. An organic EL device comprising:
an insulative substrate;
a first switching element and a second switching element, which are above the insulative substrate;
an insulation film above the first switching element and the second switching element and comprising a first contact hole reaching the first switching element and a second contact hole reaching the second switching element;
a first pixel electrode above on the insulation film and comprising a first contact portion extending into the first contact hole and electrically connected to the first switching element;
a second pixel electrode above the insulation film with being spaced apart from the first pixel electrode, and comprising a second contact portion extending into the second contact hole and electrically connected to the second switching element;
an organic layer extending over the first pixel electrode including the first contact portion, extending over the second pixel electrode including the second contact portion, and extending over the insulation film between the first pixel electrode and the second pixel electrode; and
a counter-electrode above the organic layer.

14. The organic EL device of claim 13, wherein each of the first pixel electrode and the second pixel electrode includes (a) a reflective layer which has an upper surface and a first side surface, is above the insulation film, and extends into the contact hole, and a transmissive layer which is on the upper surface of the reflective layer and comprises a second side surface at a position agreeing with a position immediately above the first side surface, or includes (b) a reflective layer which has an upper surface and is disposed on the insulation film, and a transmissive layer which is stacked on the upper surface of the reflective layer and extends into the contact hole, or includes (c) a reflective layer which has an upper surface and a first side surface, and is above the insulation film, and a transmissive layer which is on the upper surface of the reflective layer, has a second side surface at a part of a position inside a position immediately above the first side surface, and extends into the contact hole.

15. The organic EL device of claim 14, wherein the insulation film has a first upper surface on which the first pixel electrode and the second pixel electrode are disposed, and a second upper surface which is located between the first pixel electrode and the second pixel electrode and is recessed from the first upper surface.

16. The organic EL device of claim 13, wherein the insulation film has a first upper surface on which the first pixel electrode and the second pixel electrode are disposed, and a second upper surface which is located between the first pixel electrode and the second pixel electrode and is recessed from the first upper surface.

17. The organic EL device of claim 13, wherein a taper angle of the contact hole in the insulation film is 40° or less.

18. The organic EL device of claim 13, wherein a film thickness of the organic layer is greater than a film thickness of the first pixel electrode and the second pixel electrode.

19. A method of manufacturing an organic EL device, comprising:
forming a switching element above an insulative substrate;
coating an insulation film material on the switching element and patterning the insulation film material to form a contact hole reaching the switching element;
forming an insulation film by baking the insulation film material and then cooling the insulation film material;
forming an electrically conductive layer on the insulation film and in the contact hole, and patterning the electrically conductive layer to form a pixel electrode which is electrically connected to the switching element;
forming an organic layer on the pixel electrode and on the insulation film in a vicinity of the pixel electrode; and
forming a counter-electrode on the organic layer.

20. The method of claim 19, wherein a temperature for baking the insulation film material is a which is on the upper surface of the reflective layer and extends into the contact hole, or includes (c) a reflective layer which has an upper surface and a first side surface, and is above the insulation film, and a transmissive layer which is on the upper surface of the reflective layer, has a second side surface at a part of a position inside a position immediately above the first side surface, and extends into the contact hole.

3. The organic EL device of claim 2, wherein the insulation film comprises a first upper surface on which the pixel electrode is disposed, and a second upper surface which is located in a vicinity of the pixel electrode and is recessed from the first upper surface.

4. The organic EL device of claim 1, wherein the insulation film comprises a first upper surface on which the pixel electrode is disposed, and a second upper surface which is located in a vicinity of the pixel electrode and is recessed from the first upper surface.

5. The organic EL device of claim 1, wherein a taper angle of the contact hole in the insulation film is 40° or less.

6. The organic EL device of claim 1, wherein a film thickness of the organic layer is greater than a film thickness of the pixel electrode.

7. An organic EL device comprising:
temperature at which the insulation film material transitions to a molten state.
